(19) United States
(12) Patent Application Publication
(10) Pub. No.: US 2019/0123219 A1
(43) Pub. Date: Apr. 25, 2019

(54) PROCESS FOR COVERING A PHOTOVOLTAIC SURFACE AND PHOTOVOLTAIC SURFACE MADE THROUGH SUCH PROCESS

(71) Applicants: Fabrizio CHIARA, San Francesco al Campo (IT); Giancarlo CASELLATO, Torino (IT)

(72) Inventors: Fabrizio CHIARA, San Francesco al Campo (IT); Giancarlo CASELLATO, Torino (IT)

(21) Appl. No.: 16/089,239

(22) PCT Filed: Mar. 6, 2017
(86) PCT No.: PCT/IT2017/000044

§ 371 Date: Sep. 27, 2018

(30) Foreign Application Priority Data
Mar. 30, 2016 (IT) 102016000032383

(51) Int. Cl. H01L 31/0216; H01L 31/18

(52) U.S. Cl. CPC H01L 31/02167; B44F 99/00; H01L 31/18

(57) ABSTRACT

A process is described for covering a photovoltaic surface comprising the steps of providing a graphic representation and a photovoltaic surface, making a graphic grid (1) composed of an empty area (B) and a filled area (D), associating the graphic representation to the graphic grid (1) to obtain a perforated graphic representation according to the areas (B, D), and at least partially covering the photovoltaic surface with the graphic representation through the graphic grid (1). A photovoltaic surface made through this process is further described.

The present invention refers to a process for covering a photovoltaic surface, in particular through an embodiment and an application of a graphic representation on such photovoltaic surface and to a photovoltaic surface made through such process.

Today the use of alternative technologies is more and more widespread: in particular, an optical-electronic device, such as a photovoltaic or solar panel, is known, composed of photovoltaic or solar cells, capable of converting the incident sun energy into electric energy through a photovoltaic effect, and it is typically used as current generator in a photovoltaic or solar plant.

The strong diffusion and installation of photovoltaic or solar panels in a plurality of external and internal environments, such as for example gardens, plane or incline roofs, shelters, etc. is also known, implying a high visual impact.

Moreover, photovoltaic and solar panels are known, mainly of a dark colour, which enable the process of converting solar Energy, but prevent its camouflaging with the surrounding environment in which they are installed.

A device is also known, like the one described, for example, in patent US2016072430, composed of a solar panel, of a transparent slab equipped on the external surface with a printed image and inside with a plurality of optical means adapted to re-address the luminous rays on the printed image on the slab surface. Moreover, this printed image is composed of opaque or semi-transparent areas, separated by totally transparent areas or micro-holes. Such device enables the illumination of the printed image on the slab surface, but does not ensure a high efficiency of use of the solar panel; moreover, such solar panel is designed for a particular graphic element, limiting the applicability of the device.

A technologic process is also known in the art, characterized by a production of a solar ink capable of capturing light and convert it into electricity. The technologic process is performer with suitable printers, through a digital printing technique, which can be applied on multiple surfaces, such as for example a surface made of PET (polyethylene terephtalate) plastic, through the distribution of solar ink, performing the transformation of such PET plastic surface into a photovoltaic panel. The known technologic process implies a low production and process cost, the use of daily used materials, and a practical application use, but it is not able to guarantee photovoltaic panels with high performances, comparable with the power delivered by those normally known in the art.

It is clear from the known prior art that currently the photovoltaic or solar devices have a strong visual impact, preventing the integration in environments where aesthetic and design are required, and the proposed solutions to reduce such visual impact do not guarantee an operating conversion efficiency.

Therefore, object of the present invention is solving the above prior art problems by providing a process capable of covering a photovoltaic surface with a graphic representation.

Another object is providing a graphic element equipped with empty and filled areas capable of guaranteeing a high operating efficiency for converting the photovoltaic surface.

Moreover, an object of the present invention is providing a photovoltaic surface covered with a graphic representation though keeping a high operating converson efficiency.

The above and other objects and advantages of the invention, as will appear from the following description, are obtained with a process for covering a photovoltaic surface and with a photovoltaic surface as claimed in the respective independent claims. Preferred embodiments and non-trivial variations of the present invention are the subject matter of the dependent claims.

It is intended that all enclosed claims are an integral part of the present description.

It will be immediately obvious that numerous variations and modifications (for example related to shape, sizes, arrangements and parts with equivalent functionality) could be made to what is described, without departing from the scope of the invention as appears from the enclosed claims.

The present invention will be better described by some preferred embodiments thereof, provided as a non-limiting example, with reference to the enclosed drawings, in which:

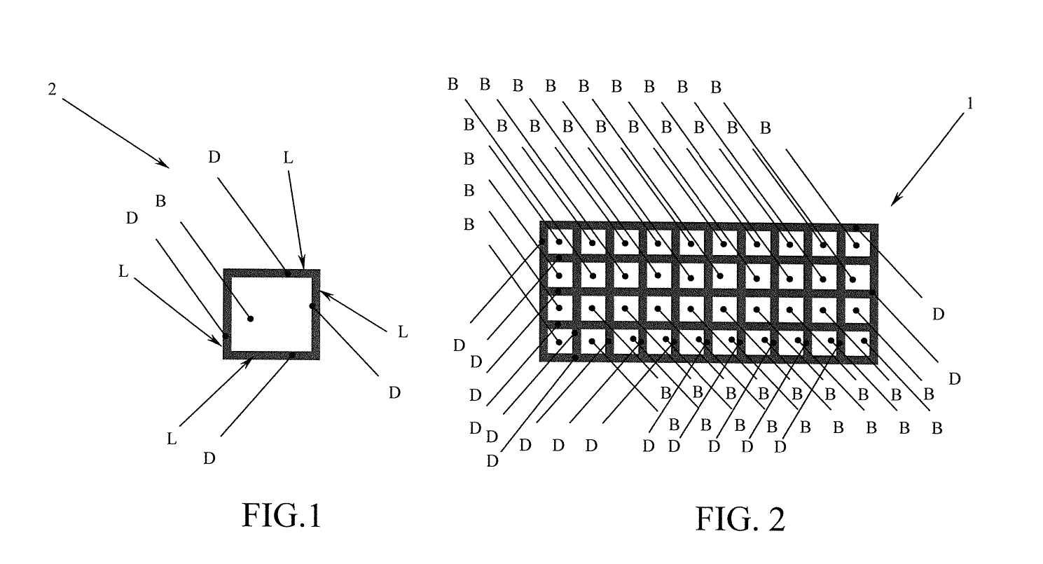

FIGS. 1 and 2 show front views of a preferred embodiment of components of the process for covering a photovoltaic surface according to the present invention; and

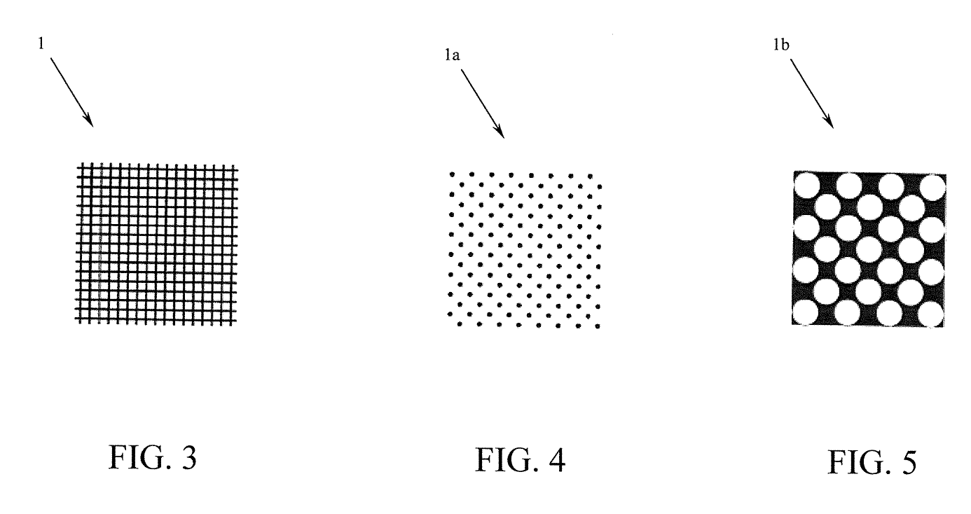

FIGS. 3 to 5 show front views of three preferred embodiments of components of the process for covering a photovoltaic surface according to the present invention.

With reference to the Figures, it is possible to note that the process for covering at least one photovoltaic, rigid or flexible surface and, advantageously, any surface adapted to convert a radiation of the optical spectrum such as infrared, or ultraviolet, etc. into electricity to obtain an optimization of the operating conversion efficiency of such photovoltaic surface with at least one graphic representation, substantially comprises the steps of:
providing at least one graphic representation and at least one photovoltaic surface on which such graphic representation has to be applied;
making at least one graphic grid 1 composed of at least one empty area B and at least one filled area D: preferably, a percentage ratio E between such areas B, D is included between 10% and 90%;
associating the graphic representation to the graphic grid 1 to obtain such perforated graphic representation (virtually or materially) according to such areas B, D; and
at least partially covering such photovoltaic surface with such perforated graphic representation.

In particular, the perforated graphic representation can advantageously be applied as covering of such photovoltaic surface through:
directly printing with the insertion of the photovoltaic surface inside a suitable printer, such as, for example, a ROLAND VersaUV LEF-20 printer with UV inks or other similar one, with possible following covering with at least one transparent protecting layer; and/or
separately making the perforated graphic representation with suitable removal of the empty areas B from the filled areas D according to the graphic grid 1 and afterwards gluing onto the photovoltaic surface; and/or
printing the perforated graphic representation on a suitably transparent support to be glued or mechanically or chemically fastened onto the photovoltaic surface.

The process according to the present invention can further comprise the steps of:
defining at least one elementary graphic element 2 such as, for example, a pattern element or other suitable one;
making such graphic grid 1 composed of a plurality of such elementary graphic elements 2.

In particular, the graphic grid 1 can be composed of a plurality of such elementary graphic elements 2 like, for example, a grid with a rectangular, hexagonal, circular, square or other similar shape, or with an arrangement with dimples 1a, as shown in FIG. 2, or with an arrangement with negative dimples 1b, as shown in FIG. 3.

As shown in FIG. 2, the graphic grid 1 can be obtained through a repetition of the elementary graphic element 2 along the three space directions and, in particular, obtained through a rotary symmetry if the elementary graphic element 2 is repeated around a rotation centre, or through a translation symmetry if the elementary graphic element 2 is repeated through movement along a line or a surface, or through mirror symmetry if the elementary graphic element 2 is repeated through an overturning with respect to a rotation axis.

In particular, the graphic grid 1, or the single elementary graphic element 2, is defined through a suitable development tool such as, for example, Photoshop, or Corel Draw, or GIMP (GNU Image Manipulation Program) or other similar one, so that it is equipped with at least one empty area B adapted to enable the incidence of the sun light on the photovoltaic surface and with at least one filled area D adapted to compose the application zone of the graphic representation; consequently, the elementary graphic element 2 and the related graphic grid 1 are equipped with empty and filled areas according to a percentage ratio E included between value 10% and value 90%, enabling the optimization of the operating conversion efficiency of the photovoltaic surface covered with the graphic elemento through such process for covering.

FIG. 1 shows, as a non-limiting example, the elementary graphic element 2 having a square shape, equipped with a total area A equal to the square of a size of the side L of the elementary graphic element 2, according to a first relationship A=L²; and equipped with an empty area B related to the size of the side L and to a size of the filled area D of the elementary graphic element 2, represented by the thickness of the side L of the total area A, according to a second relationship equal to B=(L−2D)². The percentage ratio E characterizing the elementary graphic element 2 is equal to a ratio between empty area B and total area A, according to a third relationship equal to

$$E = \frac{{( L - 2 D )}^{2}}{{L}^{2}}$$

In particular, the size of the side L of the total area A of the elementary graphic element 2 is such as to make the elementary graphic element 2, at the end of the process for covering the photovoltaic surface, not capable of being visually distinguished from the graphic representation, allowing a sharp display of the representation itself.

The present invention further deals with a photovoltaic, rigid or flexible surface, covered at least partially with at least one graphic representation through the above described process. In particular, such photovoltaic surface according to the present invention is covered with at least one perforated graphic representation defined by at least one graphic grid 1 composed of at least one empty area B and at least one filled area D, so that a percentage ratio E between such areas B, D is included between 10% and 90%.

1. Process for covering at least one photovoltaic surface comprising the steps of:
providing at least one graphic representation and at least one photovoltaic surface, said graphic representation being adapted to confer aesthetic properties to said photovoltaic surface;
making at least one graphic grid composed of at least one empty area and at least one filled area;
associating said graphic representation to said graphic grid to obtain a perforated graphic representation according to said areas; and
covering at least partially said photovoltaic surface with said perforated graphic representation,
said process being characterized in that a percentage ratio between said areas is included between 10% and 90%.

2. Process according to claim 1, characterized in that it further comprises the steps of:
defining at least one elementary graphic element;
making said graphic grid composed of a plurality of said elementary graphic elements.

3. Process according to claim 1, characterized in that said empty area is adapted to enable an incidence of sun light on said photovoltaic surface and said filled area is adapted to compose an application zone of said graphic representation.

4. Process according to claim 1, characterized in that said perforated graphic representation is applied as covering for said photovoltaic surface through:
directly printing through an insertion of said photovoltaic surface inside at least one printer; and/or
separately making said graphic representation with suitable removal of said empty areas from said filled areas according to said graphic grid and afterwards gluing onto said photovoltaic surface; and/or
printing said perforated graphic representation on at least one suitably transparent support to be glued or fastened onto said photovoltaic surface.

5. Process according to claim 2, characterized in that said graphic grid is obtained through a repetition of said elementary graphic element along three space directions, through at least one rotary symmetry if said elementary graphic element is repeated around ad at least one rotation centre, or through a translation symmetry if said elementary graphic element is repeated through at least one movement along a line, or through a mirror symmetry if said elementary graphic element is repeated through at least one overturning with respect to a rotation axis.

6. Process according to claim 2, characterized in that said elementary graphic element is equipped with a total area equal to the square of at least one size of a side of said elementary graphic element, according to a first relationship A=L², and equipped with at least one empty area related to said size of said side and ad at least one size of at least one filled area of said elementary graphic element, equal to at least one thickness value of said side of said total area, according to a second relationship B=(L−2D)².

7. Process according to claim 6, characterized in that said elementary graphic element has at least one value of said percentage ratio equal to at least one ratio between said empty area and said total area, according to a third relationship
$$E = \frac{{( L - 2 D )}^{2}}{{L}^{2}} .$$

8. Photovoltaic surface, characterized in that it is covered at least partially with at least one graphic representation through a process according to claim 1.

9. Photovoltaic surface according to claim 8, characterized in that said perforated graphic representation is defined by at least one of said graphic grids composed of at least one of said empty areas and at least one of said filled areas so that a percentage ratio between said areas is included between 10% and 90%.
